(19) United States
(12) Patent Application Publication
(10) Pub. No.: US 2009/0058283 A1
(43) Pub. Date: Mar. 5, 2009

(54) Display device

(75) Inventors: Masahiro Tanaka, Chiba (JP); Toshiyuki Matsuura, Mobara (JP)

Correspondence Address: Stanley P. Fisher;Reed Smith LLP, Suite 1400, 3110 Fairview Park Drive, Falls Church, VA, 22042-4503, US

(73) Assignee: Hitachi Displays, Ltd.

(21) Appl. No.: 12/230,768

(22) Filed: Sep. 4, 2008

(30) Foreign Application Priority Data
Sep. 5, 2007 (JP) 2007-229895

(51) Int. Cl. H01J 1/62

(52) U.S. Cl. 313/504

(57) ABSTRACT

To realize a top emission type organic electroluminescent display device which requires a small number of processes, and provides good color purity, and manufacturing yield. A transparent conduction film of 5 nm to 20 nm is formed on a lower electrode. An organic electroluminescent layer is sandwiched between the transparent conduction film and an upper electrode. The transparent conduction film is formed of indium tin oxide, and an indium tin oxide resistivity is controlled to a value of 1 to 10⁵Ω·cm by controlling sputtering conditions. The electrical resistance of the indium tin oxide film controlled in this way can be low enough in a film thickness direction to supply a voltage to the organic electroluminescent layer, and, in a film planar direction, as high as in an insulated condition. Consequently, it is possible to maintain necessary properties even though the indium tin oxide is deposited over a whole of a substrate. According to the invention, it is possible to eliminate a process of patterning the indium tin oxide on the lower electrode.

### CLAIM OF PRIORITY

The present application claims priority from Japanese Application JP 2007-229895 filed on Sep. 5, 2007, the content of which is hereby incorporated by reference into this application.

### BACKGROUND OF THE INVENTION

1. Technical Field

The present invention relates to a display device, particular relates to a top emission type organic electroluminescent display device which enables a lowering of a cost while maintaining a high image quality.

2. Related Art

As an organic electroluminescent display device, there are of a bottom emission type, which extracts a light emitted from an organic electroluminescent layer in a direction of a glass substrate on which are formed the organic electroluminescent layer and so on, and of a top emission type, which extracts the light in a direction opposite to the glass substrate on which are formed the organic electroluminescent layer and so on. The top emission type has an advantage in that, as it is possible to take a large area for the organic electroluminescent layer, it is possible to increase a brightness of a display.

In an organic electroluminescent display device, the organic electroluminescent layer is sandwiched between a pixel electrode (a lower electrode) and an upper electrode, and an image is formed by applying a constant voltage to the upper electrode, and applying a data signal voltage to the lower electrode, controlling an emission of light from the organic electroluminescent layer. A supply of the data signal voltage to the lower electrode is carried out via a thin film transistor (TFT). With the top emission type organic electroluminescent display device, as it is possible to form the organic electroluminescent layer on the TFT etc. too, it is possible to increase a light emitting area.

As the top emission type organic electroluminescent display device emits light on the upper electrode side, it is necessary that the lower electrode uses a metal such as aluminum or silver, which has a high light reflectivity. With the top emission type organic electroluminescent display device, there is a case in which the lower electrode is used as an anode. In this case, as a work function of the metal such as aluminum is low, it is not appropriate to use it as the anode.

In JP-A-2007-35432, it is stated that the lower electrode is caused to function as the anode by coating the lower electrode with a transparent conduction film of indium tin oxide, indium zinc oxide, or the like. In JP-A-2007-35432, also, it is stated that by forming the transparent conduction film comparatively thinly on the lower electrode, which is a metal, and subsequently polishing it, a surface of the transparent conduction film is planarized, and a thickness of the transparent conduction film is made to be a predetermined value or less.

### SUMMARY OF THE INVENTION

As heretofore described, with the top emission type organic electroluminescent display device anode, a transparent conduction film, such as indium tin oxide or indium zinc oxide, is formed on a reflective layer. In this case, as a color of an emitted light changes slightly due to an interference effect of light, an optical design is essential. When using a transparent conduction film with a thickness common to the three primary colors, the thinner the transparent conduction film, the higher a degree of freedom in the optical design, and it is possible to acquire emitted light colors nearer to the primary colors.

However, there has been a problem in that, pinholes being liable to form when making the indium tin oxide or indium zinc oxide thin, it is easy to damage a base reflective layer when processing the transparent conduction film. With the technology described in JP-A-2007-35432, it is stated that the indium tin oxide is deposited comparatively thickly, and the indium tin oxide is subsequently polished, forming a desired thickness. With the technology described in JP-A-2007-35432, it being necessary to pattern the indium tin oxide, using a photolithography, for each pixel after depositing the indium tin oxide, a cost balloons. Also, an etching residue or the like is liable to occur due to patterning the indium tin oxide. Furthermore, although it is necessary to polish the indium tin oxide to one quarter or less of a minimum emission wavelength λ, a cost of the polishing process, processing defects occurring in the polishing process, and the like, are also problems.

Another issue of the invention is a problem of, in a case of using aluminum as the lower electrode, a contact between the aluminum and the transparent conduction film. As a surface of aluminum oxidizes easily, and oxidized aluminum has a high resistance, a contact resistance between the aluminum and the transparent conduction film is a problem.

An object of the invention is to solve the heretofore described kinds of problems, and realize a top emission type organic electroluminescent display device which, while maintaining a superior color purity, has a good manufacturing yield rate, and suppresses an increase in processing steps of indium tin oxide or the like.

The invention, in order to solve the heretofore described problems, provides a configuration whereby, by specifying a resistivity of the transparent conduction film on the lower electrode, necessary functions of the transparent conduction film can be maintained, even without carrying out a processing of the transparent conduction film. That is, when increasing an oxygen concentration at a time of a sputtering, the resistivity of the transparent conduction film increases. However, as a work function increases, a hole injection property is maintained. Then, a resistivity and film thickness are selected for the transparent conduction film such that a resistance in a film thickness direction is made low enough to allow a current to flow, while a resistance in a film lateral direction is high, and the current barely flows. By so doing, even without processing the indium tin oxide, it is possible to maintain the hole injection property of the anode, while preventing an occurrence of another side-effect.

The other issue of the invention is the problem of the contact between the aluminum and the transparent conduction film. In order to reduce the contact resistance between the aluminum and the transparent conduction film, it is sufficient to remove an oxide film from the aluminum surface. On the aluminum being immersed in a zinc chloride solution, the surface oxide film dissolves, and zinc is slightly separated out. As the zinc is a semi-conductor even though it is oxidized, a conductivity is maintained. By forming indium tin oxide or indium zinc oxide on a surface coating made of the zinc (Zn) or zinc oxide (ZnO), it is possible to secure an electrical contact between the lower electrode and the transparent conduction film.

A specific configuration is as described hereafter.

(1) An organic electroluminescent display device in which pixels having a lower electrode, an organic electroluminescent layer, and an upper electrode are formed in a matrix, forming a display area, and a terminal is formed on an external side of the display area, wherein a transparent conduction film is formed between the lower electrode and the organic electroluminescent layer, and the transparent conduction film is formed continuously between a first lower electrode and a second lower electrode too.

(2) The organic electroluminescent display device according to (1), wherein a thickness of the transparent conduction film is 5 to 20 nm, and a resistivity is 1 to 10⁵ Ω·cm.

(3) The organic electroluminescent display device according to (1), wherein the thickness of the transparent conduction film is 10 to 20 nm, and the resistivity is 1 to 105 Ω·cm.

(4) The organic electroluminescent display device according to (2), wherein the transparent conduction film is formed as a continuous film between the first electrode and second electrode too.

(5) The organic electroluminescent display device according to (1), wherein the transparent conduction film is of indium tin oxide.

(6) The organic electroluminescent display device according to (1), wherein the transparent conduction film is of indium zinc oxide.

(7) The organic electroluminescent display device according to (1), wherein the lower electrode is formed of an aluminum-zinc alloy.

(8) The organic electroluminescent display device according to (1), wherein the lower electrode is formed of an aluminum-nickel alloy.

(9) The organic electroluminescent display device according to (1), wherein the lower electrode is formed of an aluminum-silicon alloy.

(10) An organic electroluminescent display device in which pixels having a lower electrode, an organic electroluminescent layer, and an upper electrode are formed in a matrix, forming a display area, and a terminal is formed on an external side of the display area, wherein a transparent conduction film is formed between the lower electrode and the organic electroluminescent layer, a bank is formed between a first lower electrode and a second lower electrode, and the transparent conduction film is formed continuously on the bank too.

(11) The organic electroluminescent display device according to (10), wherein the organic electroluminescent layer is formed continuously on the bank.

(12) An organic electroluminescent display device in which pixels having a lower electrode, an organic electroluminescent layer, and an upper electrode are formed in a matrix, forming a display area, and a terminal is formed on an external side of the display area, wherein a transparent conduction film is formed between the lower electrode and the organic electroluminescent layer, a thin film made of zinc or zinc oxide is formed between the transparent conduction film and the lower electrode, and the transparent conduction film is formed continuously between a first lower electrode and a second lower electrode too.

(13) The organic electroluminescent display device according to (12), wherein the transparent conduction film is of indium zinc oxide.

(14) The organic electroluminescent display device according to (12), wherein the lower electrode is formed of any one of an aluminum-silicon alloy, an aluminum-neodymium alloy, or an aluminum-copper alloy.

According to the invention, as it is possible to render unnecessary a patterning of the transparent conduction film on the lower electrode, it is possible to reduce a manufacturing cost by reducing the number of processes. Also, according to the invention, as it is possible to render unnecessary a patterning of the transparent conduction film on the lower electrode, it being possible to prevent damage to the lower electrode accompanying a patterning of the transparent conduction film, it is possible to prevent a reduction in the manufacturing yield. Furthermore, according to the invention, as it is possible to form the transparent conduction film thinly on the lower electrode, it is possible to suppress a reduction in the color purity of the light emitted from the organic electroluminescent layer.

According to another aspect of the invention, by forming a surface coating made of zinc or zinc oxide on a surface of the lower electrode, it being possible to reduce the contact resistance between the lower electrode and the transparent conduction film, it is possible to suppress an increase in a voltage applied to cause the organic electroluminescent layer to emit light.

### BRIEF DESCRIPTION OF THE DRAWINGS

FIG. 1 is a sectional view of an organic electroluminescent display device of a first embodiment;

FIG. 2 is a sectional view of a pixel portion of the first embodiment;

FIG. 3 is a sectional view of a terminal unit;

FIG. 4 is a sectional view of an organic electroluminescent display device of a second embodiment;

FIG. 5 is a schematic view showing a problem when a bank is omitted in a heretofore known technology;

FIG. 6 is a schematic view showing another problem when the bank is omitted in the heretofore known technology;

FIG. 7 is a sectional view of a pixel portion of the second embodiment;

FIG. 8 is a sectional view of a contact hole of the second embodiment;

FIG. 9 is a layout view of pixels in the second embodiment;

FIG. 10 is another example of a layout view of the pixels in the second embodiment; and

FIG. 11 is a sectional view of a pixel portion of a third embodiment.

### DESCRIPTION OF THE PREFERRED EMBODIMENTS

In an organic electroluminescent display device, pixels configured of a pixel electrode, which is a lower electrode, an organic electroluminescent layer, and an upper electrode are formed in a matrix, forming a display area. The individual pixels take charge of a red light emission, a green light emission, or a blue light emission. Then, an appliance of a voltage, or a supply of a current, to each pixel is controlled by a plurality of thin film transistors (TFTs). A terminal unit for supplying power or a signal to the pixels from an exterior is formed on an external side of the display area. Hereafter, detailed contents of the invention will be disclosed in accordance with embodiments.

### First Embodiment

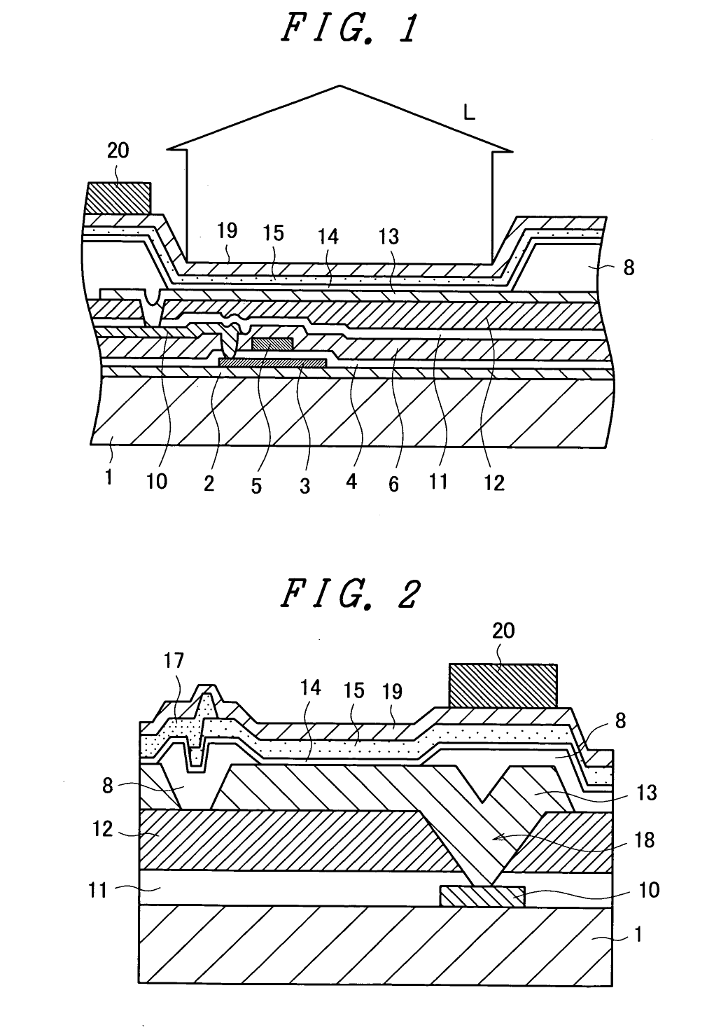

FIG. 1 is a sectional view of a top emission type organic electroluminescent display device according to the invention. In FIG. 1, a base film 2 for blocking impurities from glass is formed on a glass substrate 1. While there is a case in which one layer of a silicon nitride film or the like is formed as the base film 2, there is also a case in which the base film 2 is made of two layers, one each of a silicon nitride film and a silicon dioxide film. A semi-conductor layer 3 for configuring a TFT being formed on the base film 2, a gate insulating film 4 is formed covering the semi-conductor layer 3. In the embodiment, the semi-conductor layer 3 is an amorphous silicon film converted into a poly-silicon film by a laser annealing. A gate electrode 5, which is one portion of a gate wiring 5, is formed on the gate insulating film 4. The TFT of FIG. 1 is a top gate type TFT.

An inter-layer insulating film 6 being formed covering the gate electrode 5, a source/drain wiring (an SD wiring 10) is formed on the inter-layer insulating film 6. A passivation film 11 for protecting a whole of the TFT is formed covering the SD wiring 10. A planarizing film 12 made of a resin is formed on the passivation film 11. The planarizing film 12 is formed thickly at around 2 μm. A surface formed by the TFT etc. is irregular. In the top emission type organic electroluminescent display device, an organic electroluminescent layer is also formed on the TFT etc., but it is necessary to form the organic electroluminescent layer on a flat film. A surface on which the organic electroluminescent layer is formed is planarized by forming the resin thickly.

A lower electrode 13 is formed on the planarizing film 12. An aluminum-zinc alloy, whose contact resistance with indium tin oxide is low, is used for the lower electrode 13. The aluminum-zinc alloy is deposited by means of a sputtering to a thickness of 120 nm, a pattern is formed using a photoresist, and an etching is done using phosphoric acid, acetic acid or nitric acid, forming the lower electrode 13.

Subsequently, a pattern covering a pixel periphery is formed with a photosensitive acrylic. An object of this is to prevent a short circuiting of the lower electrode 13 and an upper electrode 19, without an organic electroluminescent layer, which is an evaporated film, completely covering an unevenness of an extremity of the lower electrode 13. Hereafter, this portion will be called a bank 8.

After forming the bank 8, a thin indium tin oxide film is formed by a sputtering to a thickness of 20 nm over a whole surface, including the bank 8. Although the indium tin oxide is formed over the whole substrate, no problem occurs, as will be described hereafter. Subsequently, an organic electroluminescent layer is formed using a mask evaporation. The organic electroluminescent layer is normally formed of a plurality of layers. Subsequently, an indium zinc oxide, which is the transparent upper electrode 19, is deposited. It being sufficient that the upper electrode 19 is transparent, indium tin oxide is also acceptable. The smaller a resistance of the transparent upper electrode 19 the better, but there may be a case that it is not possible to make the resistance sufficiently small due to a restriction of a film thickness or a resistivity. For this reason, an auxiliary electrode 20 is formed above the bank 8, which is not a hindrance to an extraction of light from the organic electroluminescent layer.

FIG. 2 is an enlarged schematic view of an extracted vicinity of the lower electrode 13 of FIG. 1. Positions of the lower electrode 13 with respect to a contact hole 18 in FIGS. 1 and 2 are reversed. Although, in FIG. 2, the SD wiring 10 is shown as being formed on the glass substrate 1, this being in order to simplify the drawing, actually the inter-layer insulating film 6, the gate insulating film 4, the base film 2 etc., exist below the SD wiring 10.

In FIG. 2, the passivation film 11 and the planarizing film 12 are formed covering the SD wiring 10. The lower electrode 13 is formed on the planarizing film 12. The lower electrode 13 is patterned using a photolithography. The lower electrode 13 has continuity with an SD wiring via the contact hole 18 formed in the planarizing film 12 and passivation film 11. Indium tin oxide, which is a transparent conduction film 14, is thinly deposited by a sputtering to a thickness of around 20 nm on the lower electrode 13.

As a method of reducing a contact resistance between the aluminum alloy and the indium tin oxide or indium zinc oxide, which is the transparent conduction film 14, it is possible to use a kind of method which maintains a conductivity even though a surface of the aluminum alloy is oxidized, or to employ a method which, by a reverse sputtering of the surface of the aluminum alloy, removes a natural oxide film, and subsequently sputters the indium tin oxide or indium zinc oxide. Also, in a case of using silver as the lower electrode 13, the indium tin oxide or indium zinc oxide is sputtered immediately after patterning the silver.

As a condition of the indium tin oxide sputtering, a discharge gas is argon, and 2% by volume of oxygen is introduced. A resistivity of the indium tin oxide formed by this kind of sputtering is 5 to 200 Ω·cm. Although a fluctuation of the resistivity is quite large, as a resistance of an organic electroluminescent layer is considerably larger than this value, it does not happen that the fluctuation affects a property. Meanwhile, a resistance of an indium tin oxide in lateral direction is extremely large. Consequently, even though the indium tin oxide is deposited over the whole substrate, no problem occurs.

The organic electroluminescent layer is formed by an evaporation on the ITO film, and on top of that the upper electrode 19 is formed of indium zinc oxide. The auxiliary electrode 20 is formed above the bank 8 which does not hinder the extraction of light from the organic electroluminescent layer. The auxiliary electrode 20 has a role of assisting in a conduction of the upper electrode 19, and a role of preventing an emission of waveguide light from the contact hole 18.

In FIG. 2, the bank 8 being formed in a portion where the lower electrode 13 and lower electrode 13 are separated, the organic electroluminescent layer is also formed on the bank 8, and one portion thereof overlaps a neighboring organic electroluminescent layer. In this way, by causing the organic electroluminescent layers to overlap, it is possible to further reduce a danger of a short circuiting of the lower electrode 13 and the upper electrode 19. As the lower electrode 13 does not exist in the overlapping portion of the organic electroluminescent layers, it does not happen that this portion emits light.

In FIG. 2, the indium tin oxide, which is the transparent conduction film 14 covering the lower electrode 13, being formed over the whole of the substrate, it is deposited in every place on the substrate, both on the pixels and between the pixels, also, both on terminals and between the terminals, and furthermore on sealing portions and the like, but it does not cause a problem for the property.

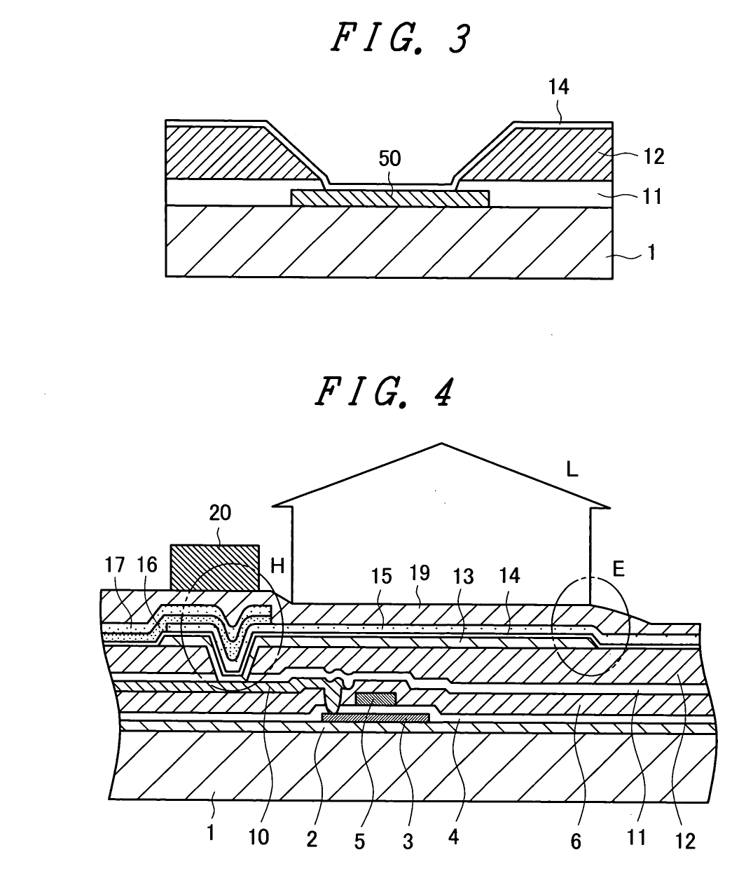

FIG. 3 is a sectional view of a terminal unit. In FIG. 3, a terminal wiring 50 is the SD wiring 10 or the gate wiring 5 pulled out to a substrate extremity. In the event that a current flowing to the terminal unit is large, the SD wiring 10, which has a small resistance, is used as the terminal wiring 50. The passivation film 11 and the planarizing film 12 being deposited covering the terminal wiring 50, an opening is provided in these films. Subsequently, indium tin oxide is thinly deposited in order to protect the terminal wiring 50 from the atmosphere. The depositing of the indium tin oxide is carried out simultaneously with the depositing of the transparent conduction film 14 on the lower electrode 13 in a pixel portion.

Although the indium tin oxide film is deposited over the terminal unit and between terminal units, as long as a thickness of the indium tin oxide film is 5 to 20 nm, and a resistivity is in a range of 1 to 10⁵ Ω·cm, a kind of phenomenon that a resistance in the terminal unit is too high, a resistance between the terminal units becomes small, or an insulation cannot be maintained does not occur. For this reason, in the embodiment, a thin indium tin oxide is deposited over the whole of the substrate surface. It is more preferable that the thickness of the indium tin oxide film is 10 to 20 nm. This is because, by being in this range, the indium tin oxide can exist more stably as a film.

Meanwhile, it is also possible to arrange in such a way that the indium tin oxide film is not deposited between the terminals by sputtering with a mask covering an area between terminal and terminal. In this case, a resistivity parameter of the indium tin oxide film widening further, it is sufficient that it is in a range of 0.1 to 5×10⁶ Ω·cm. That is, as long as the indium tin oxide resistivity is within this range, it does not happen either that a light emission voltage rises due to the indium tin oxide resistance being too large, or that a neighboring pixel emits light due to the resistance being too low.

Returning to FIG. 2, a hole transport layer, a light emitting layer, an electron transport layer, and an electron injection layer are formed by a mask evaporation as an organic electroluminescent layer on the thinly deposited indium tin oxide. Subsequently, the upper electrode 19 is formed of indium zinc oxide, and the auxiliary electrode 20 is formed so as to cover the contact hole 18. The films are formed in the following way. That is, the aluminum-zinc alloy which configures the lower electrode 13 is 120 nm, and the indium tin oxide above that is 20 nm, and the hole transport layer is 120 nm for each color commonly. Subsequently, a blue portion 17 forms the light emitting layer to 40 nm, a green portion 16 forms the hole transport layer to 60 nm and the light emitting layer to 40 nm, and a red portion 15 forms the hole transport layer to 130 nm and the light emitting layer to 30 nm. Consequently, a thickness of the hole transport layer is 120 nm in the blue portion 17, 180 nm in the green portion 16, and 250 nm in the red portion 15. On top thereof, for each color, commonly deposited are the electron transport layer to 10 nm, the electron injection layer to 60 nm, and the indium zinc oxide, which is the upper electrode 19, to 30 nm.

The hole transport layer and light emitting layer formed separately for each color are overlapped on the bank 8 formed in the portion in which the lower electrode 13 and the lower electrode 13 are separated. By so doing, it is possible to eliminate a danger of the indium tin oxide, which is the transparent conduction film 14, and the upper electrode 19 short circuiting due to an unevenness on the bank 8. Naturally, as previously described, even in the event that the indium tin oxide, which is the transparent conduction film 14, and the upper electrode 19 short circuit in a place in which the lower electrode 13 does not exist, as the indium tin oxide lateral resistance is high, there is no problem with the property.

The organic electroluminescent layer includes a plurality of layers, and the configuration is as follows. As the electron transport layer, though not particularly limited as long as it exhibits an electron transportability and is easily made into a charge transfer complex by means of a coevaporation with an alkali metal, it is possible to use, for example, a metal complex such as tris (8-quinolinolate)aluminum, tris(4-methyl-8-quinolinolate)aluminum, bis(2-methyl-8-quinolinolate)-4-phenylphenolate aluminum, or bis[2-[2-hydroxyphenyl]benzooxazolate]zinc, 2-(4-biphenylyl)-5-(4-tert-butylphenyl)-1,3,4-oxadiazole, 1,3-bis[5-(p-tert-butylphenyl)-1,3,4-oxadiazole-2-yl]benzene, or the like.

For the electron injection layer, it is acceptable to select from, for example, a metal such as an alkali metal like lithium or caesium, an alkali earth metal like magnesium or calcium, or furthermore a rare earth metal, or an oxide, a halide, a carbohydrate, or the like, thereof, formed by coevaporating a material exhibiting an electron donating property with respect to a substance used in the electron transport layer, and use it as a substance exhibiting an electron donating property.

For the hole transport layer, it is possible to use, for example, a tetraaryl benzicine compound (triphenyl diamine: TPD), an aromatic third grade amino, a hydrazone derivative, a carbazole derivative, a triazole derivative, an imidazole derivative, an oxadiazole derivative having an amino group, a polythiophene derivative, a copper phthalocyanine derivative, or the like.

As a light emitting layer material, though not particularly limited as long as it is a host material which has a capability of transporting an electron and a hole, to which is added a dopant which emits a fluorescence or a phosphorescence by means of a recombination thereof, which can be formed as the light emitting layer by means of a coevaporation, it is acceptable that as the host it is, for example, a complex such as tris(8-quinolinolate)aluminum, bis(8-quinolinolate)magnesium, bis(benzo{f}-8-quinolinolate)zinc, bis(2-methyl-8-quinolinolate)aluminum oxide, tris(8-quinolinolate)indium, tris(5-methyl-8-quinolinolate)aluminum, 8-quinolinolate lithium, tris(5-chloro-8-quinolinolate)gallium, bis(5-chloro-8-quinolinolate)calcium, 5,7-dichloro-8-quinolinolate aluminum, tris(5,7-dibromo-8-hydroxyquinolinolate)aluminum, poly[zinc(II)-bis(8-hydroxy-5-quinolinyl)methane], an anthracene derivative, a carbazole derivative, or the like.

Also, as the dopant, it is acceptable that it is a substance which captures the electron and the hole in the host, recombines them, and emits a light, for example, a substance which emits a fluorescence, such as a bilane derivative for red, a coumalin derivative for green, and an anthracene derivative for blue, or a substance which emits a phosphorescence, such as an iridium complex, or a pyridinate derivative.

It being sufficient that the upper electrode 19 is a transparent conduction film for extracting light, it is taken to be indium zinc oxide in the embodiment, but it is also acceptable that it is indium tin oxide. Also, as the upper electrode 19 is a cathode in the embodiment, it is also acceptable that a metal such as aluminum, silver, or gold is thinly formed. In this case, as it is necessary to deposit the metal thinly enough that the light penetrates, the auxiliary electrode 20 for lowering a resistance of the upper electrode 19 is necessary.

### Second Embodiment

FIG. 4 is a sectional view of a second embodiment of the invention. A difference between the embodiment and the first embodiment lies in a point that the bank 8 is not formed between the lower electrodes 13. By forming the bank 8, the number of processes increases, as it is necessary to pattern a photosensitive acryl resin by means of a photolithography. Also, an acryl resin etching residue remains on the lower electrode 13, and this has an adverse effect on a light emitting property of the organic electroluminescent layer.

Although, in order to eliminate this kind of problem, the embodiment has a configuration which does not need the bank 8, even with this kind of configuration, it is possible to apply the configuration of the invention which does not carry out a patterning on the transparent conduction film 14 on the lower electrode 13. In FIG. 4, up to the formation of the planarizing film 12 is the same as the first embodiment shown in FIG. 1.

The lower electrode 13 is formed on the planarizing film 12. An aluminum-nickel alloy, whose reflectivity is high and which has a low contact resistance with indium tin oxide, is used for the lower electrode 13. The lower electrode 13 is connected to the SD wiring 10 via the contact hole 18. A data signal is supplied to the lower electrode 13 from the SD wiring 10, and an image is formed by a voltage according to the data signal being applied to the organic electroluminescent layer. Indium tin oxide, which is the transparent conduction layer 14 for making contact with the organic electroluminescent layer, is deposited on the lower electrode 13. Then, the organic electroluminescent layer, including a plurality of layers, is formed on the transparent conduction layer 14. The organic electroluminescent layer in FIG. 4 is the red organic electroluminescent layer 15. The upper electrode 19, made of indium zinc oxide, is formed on the organic electroluminescent layer.

A structure of FIG. 4 is a top cathode structure in which the lower electrode 13 is an anode and the upper electrode 19 is a cathode. As it is necessary to let a hole into the lower electrode 13, a metal such as an aluminum alloy, which has a relatively small work function, being unsuitable, the lower electrode 13 made of aluminum-nickel is made the anode by depositing the indium tin oxide layer thereon, increasing the work function.

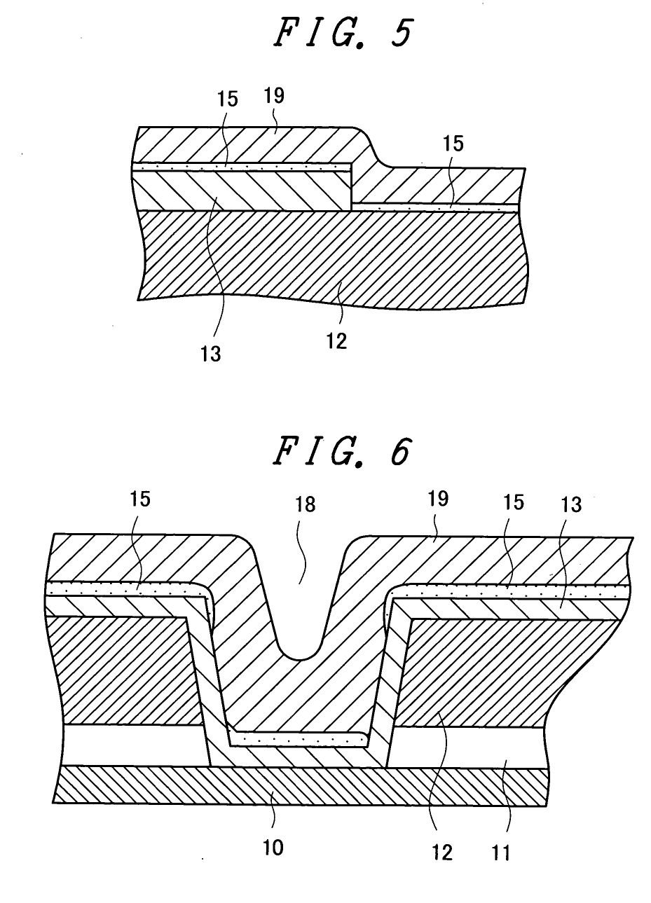

As heretofore described, the bank 8 is not formed in the invention. Problem areas in the case of not forming the bank 8 are an E portion and an H portion in FIG. 4. The E portion problem area in the case of not forming the bank 8, with the heretofore known structure as it is, is shown in FIG. 5. In FIG. 5, the lower electrode 13 is formed on the planarizing film 12. As the lower electrode 13 is only formed in a relevant pixel portion, it is patterned by means of a photolithography, and an edge portion is formed.

The organic electroluminescent layer is evaporated onto the lower electrode 13. As even an overall thickness of an evaporation layer is as thin as 100 nm to 300 nm, the kind of step shown in FIG. 5 is liable to occur at an extremity of the lower electrode 13. The upper electrode 19 is formed on the organic electroluminescent layer. As shown in FIG. 5, at the extremity of the lower electrode 13, the organic electroluminescent layer has caused a step, and the upper electrode 19 and lower electrode 13 short-circuit in the step portion. This means that the voltage is not to be applied to the organic electroluminescent layer, and the organic electroluminescent layer does not emit any light. Consequently, the pixel becomes defective.

The other problem area in the case of not forming the bank 8 is the H portion of FIG. 4. The other problem area in the case of not forming the bank 8, with the heretofore known structure as it is, is shown in FIG. 6. FIG. 6 is an enlarged view of the contact hole 18. In FIG. 6, the passivation film 11 is formed on the SD wiring 10, and the planarizing film 12 is formed on top of that. The lower electrode 13 is formed on the planarizing film 12. As it is necessary that the lower electrode 13 is connected to the SD wiring 10, the contact hole 18 is formed in the passivation film 11 and the planarizing film 12, providing a continuity between the lower electrode 13 and the SD wiring 10.

The red organic electroluminescent layer 15 is formed on the lower electrode 13, and the upper electrode 19 is formed on top of that. What is a problem here is that, while the contact hole 18 formed in the planarizing film 12 and the passivation film 11 is extremely deep at 2 μm or more, even the overall thickness of the organic electroluminescent layer is as thin as around 100 nm to 300 nm. Consequently, as shown in FIG. 6, the organic electroluminescent layer is liable to cause a step in the contact hole 18. This means that, as shown in FIG. 6, the lower electrode 13 and the upper electrode 19 bring about a short circuit phenomenon in the contact hole 18. In the event of a short circuit in the contact hole 18, the pixel becomes defective.

In response to the problem area in the E portion shown in FIG. 4, in the embodiment, as shown in FIG. 4, indium tin oxide is formed on the lower electrode 13, which is an aluminum-nickel alloy. Then, by performing a taper etching on the aluminum-nickel alloy, the step at the extremity of the organic electroluminescent layer is prevented. Also, in response to the problem area in the H portion of FIG. 4, in the embodiment, the step is prevented by depositing two or three layers of the organic electroluminescent layer, rather than only one monochromatic layer, in the contact hole 18, increasing the thickness of the organic electroluminescent layer.

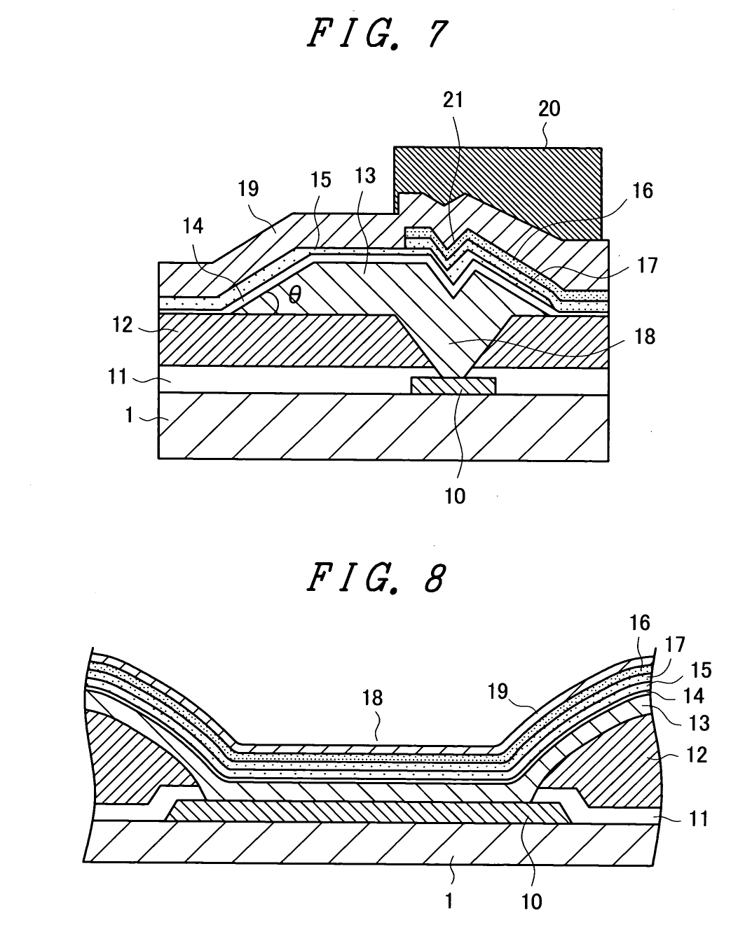

FIG. 7 is a sectional schematic view of an extracted vicinity of the lower electrode 13 of FIG. 1. Positions of the lower electrode 13 with respect to the contact hole 18 in FIGS. 4 and 7 are reversed. Although, in FIG. 7, the SD wiring is shown as being formed on the glass substrate 1, this being in order to simplify the drawing, actually the inter-layer insulating film 6, the gate insulating film 4, the base film 2 etc., exist below the SD wiring.

In FIG. 7, the passivation film 11 and the planarizing film 12 are formed covering the SD wiring 10. The lower electrode 13 is formed on the planarizing film 12. The lower electrode 13 is patterned using a photolithography. The lower electrode 13 has continuity with the SD wiring via the contact hole 18 formed in the planarizing film 12 and passivation film 11. Indium tin oxide, which is the transparent conduction film 14, is thinly deposited by a sputtering to a thickness of around 20 nm on the lower electrode 13. As the embodiment is a top cathode, as long as indium tin oxide is used as the lower electrode 13, aluminum-nickel, which is a metal, is not necessary but, in order to make the extremity of the lower electrode 13 a tapered shape, the metal lower electrode 13 is consciously used.

That is, it is possible to carry out a taper etching with indium tin oxide too. However, as the transparent conduction film 14, made of a metal oxide such as indium tin oxide, is hard and fragile, when a taper is formed, the tapered portion breaks, resulting after all in a sharp edge. In the embodiment, it is possible to reliably form a tapered edge by using an aluminum alloy, which has a resilience, for the lower electrode 13. Then, by thinly forming indium tin oxide on the lower electrode 13, it is caused to serve as the anode.

The red organic electroluminescent layer 15 is formed by an evaporation on the indium tin oxide film, and the upper electrode 19 is formed of indium zinc oxide on top of that. The auxiliary electrode 20 is formed on the upper electrode 19 where it corresponds to the contact hole 18. The auxiliary electrode 20 has the role of assisting in the conduction of the upper electrode 19, and the role of preventing the emission of waveguide light from the contact hole 18.

Although aluminum-nickel is used for the lower electrode 13, this is for the reason that, as well as the reflectivity of aluminum-nickel being high, the contact resistance with indium tin oxide is low. The lower electrode 13 is formed in the following way. That is, aluminum-nitrate is formed by means of a sputtering to a thickness of 120 nm, a pattern is formed using a photoresist, and an etching is done using a mixture of phosphoric acid, acetic acid and nitric acid.

In order to prevent a short circuiting of the lower electrode 13 and the upper electrode 19, which is caused when the organic electroluminescent layer, which is an evaporated film, does not completely cover the unevenness of the extremity of the lower electrode 13, a taper angle θ of the extremity of the lower electrode 13 is maintained at 40 degrees or less. Generally, the extremity is tapered in a just etched condition. In order to maintain the taper, it is necessary to carry out a post-etching rinsing quickly. By spraying a large amount of water in a shower form, an etching solution is quickly removed, maintaining the taper angle.

A thin film of indium tin oxide, of a thickness of 20 nm, is formed on top of that by means of a sputtering. For a discharge gas of argon, 2.5% by volume of oxygen is introduced, and an adjustment is made to an indium tin oxide film with a resistivity of 10 to 300 Ω·cm. Although a fluctuation of a resistance value is quite large, as the resistance of the organic electroluminescent layer is considerably larger than this, there is no problem as long as the resistance value is within this range.

In the same way as in the first embodiment, it is possible to evaporate indium tin oxide over the whole of the substrate surface. Although the indium tin oxide film is deposited over the terminal unit and between terminal units, as long as the thickness of the indium tin oxide film is 5 to 20 nm, and the resistivity is in the range of 1 to 10⁵Ω·cm, the kind of phenomenon that the resistance in the terminal unit is too high, or the resistance between the terminal units becomes small and the insulation cannot be maintained, does not occur. Furthermore, its being possible to widen the range of the indium tin oxide film resistivity to 0.1 to 10⁶ Ω·cm, by masking between the terminals and sputtering, is also the same as in the first embodiment. It is more preferable that the thickness of the indium tin oxide film is 10 to 20 nm. By being in this range, the indium tin oxide can exist more stably as a film.

In FIG. 7, a hole transport layer, a light emitting layer, an electron transport layer, and an electron injection layer are formed by a mask evaporation as the organic electroluminescent layer on the thinly deposited indium tin oxide. Subsequently, the upper electrode 19 is formed of indium zinc oxide, and the auxiliary electrode 20 is formed so as to cover the contact hole 18. The films are formed in the following way. That is, for each color, commonly formed are the aluminum-nitrate layer which configures the lower electrode 13 to 120 nm, the indium tin oxide above that to 20 nm, and the hole transport layer to 120 nm. Subsequently, the blue portion 17 forms the light emitting layer to 40 nm, the green portion 16 the hole transport layer to 60 nm and the light emitting layer to 40 nm, and the red portion 15 the hole transport layer to 130 nm and the light emitting layer to 30 nm. Consequently, a thickness of the hole transport layer is 120 nm in the blue portion 17, 180 nm in the green portion 16, and 250 nm in the red portion 15. On top thereof, each color commonly deposits the electron transport layer to 10 nm, the electron injection layer to 60 nm, and the indium zinc oxide, which is the upper electrode 19, to 30 nm.

The hole transport layer and light emitting layer formed separately for each color are formed so as to overlap at a border portion of each color, and the contact hole 18 is provided in an overlap portion 21 of the organic electroluminescent layers. By so doing, the organic electroluminescent layers in the contact hole 18 become thicker, a step is prevented, and it is possible to prevent a short circuit of the upper electrode 19 and the lower electrode 13. In the case of overlapping the organic electroluminescent layers, which are the red organic electroluminescent layer 15, the green organic electroluminescent layer 16, and the blue organic electroluminescent layer 17, as it becomes difficult for the current to flow when putting the blue organic electroluminescent layer 17 in the middle, it is possible to prevent an increase of a power consumption.

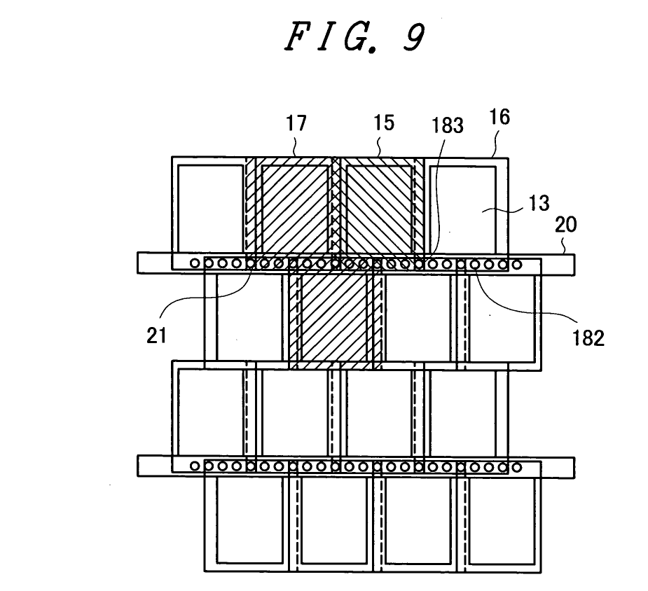

A sectional schematic view in the case of overlapping the organic electroluminescent layers is shown in FIG. 8, and a plan view thereof in FIG. 9. FIG. 8 shows that the organic electroluminescent layers are overlapping in the contact hole 18. In FIG. 8, in a case in which the organic electroluminescent layer is only for blue, a thickness is around 100 nm, and it is liable to cause a step in the contact hole 18, but when three colors of organic electroluminescent layer overlap an overall thickness becomes around 600 nm, and no step is caused. Incidentally, a thickness of organic electroluminescent layer for each color is around 100 nm for the blue color, around 200 nm for the green color, and around 300 nm for the red color. By overlapping the organic electroluminescent layers for the three colors in this way, the resistance of the organic electroluminescent layer becomes higher, it becomes difficult for the current in the contact hole 18 to flow, and it is possible to suppress the increase of the power consumption. Although it is possible to overlap the organic electroluminescent layers for the three colors in some places, only two colors are overlapped in some places. Even in this case, the danger of a step in the contact hole 18 is considerably less than in the case of only one color.

Returning to FIG. 7, even overlapping the organic electroluminescent layers does not mean that the contact hole 18 can be planarized. As the contact hole 18 is not flat, a waveguide light from the light emitting layer is output. Among light emitted from the organic electroluminescent layer, light heading toward the upper electrode 19 contributes to a formation of image. However, light heading in a direction parallel to the upper electrode 19 does not contribute to the image formation. The light heading in the direction parallel to the upper electrode 19 is called the waveguide light, but the waveguide light is visible when refracted or reflected in the contact hole 18. As the waveguide light has a high intensity, and varies in wavelength, it deteriorates an image quality. In order not to arrange in such a way as not to let the waveguide light go out to the exterior, the auxiliary electrode 20 is set over the contact hole 18.

FIG. 9 is a plan view showing a disposition of the lower electrode 13, the organic electroluminescent layer, and so on. In FIG. 9, the lower electrode 13 and the organic electroluminescent layer are disposed in a mosaic form. The organic electroluminescent layer being formed larger than the lower electrode 13, a plurality of colors of organic electroluminescent layers are overlapped in a portion in which the contact hole 18 exists. Three colors of organic electroluminescent layers being overlapped in a contact hole 183 portion, and two colors of organic electroluminescent layers are overlapped in a contact hole 182 portion. The contact hole 18 is covered by the auxiliary electrode 20 which is formed of metal.

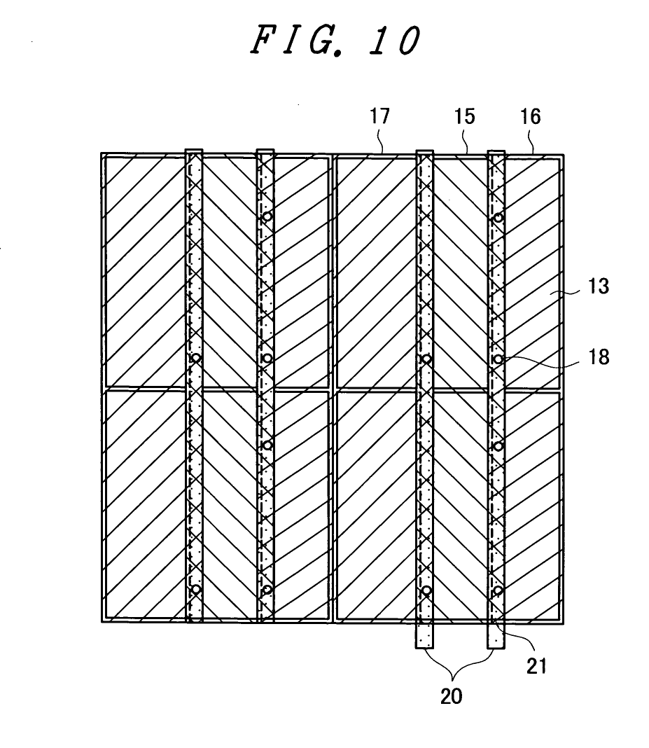

The embodiment can be applied not only to the mosaic form of arrangement of FIG. 9, but also in a case of a striped form of pixel arrangement, as shown in FIG. 10. In FIG. 10, the contact hole 18 is covered by the overlap portion 21 of the organic electroluminescent layer. Then, the overlap portion 21 of the organic electroluminescent layer is covered by the auxiliary electrode 20. FIG. 10 is a case in which the organic electroluminescent layers for two colors are overlapped in the contact hole 18. In this case too, a probability that the lower electrode 13 and the upper electrode 19 short circuit is considerably lower than the case that the organic electroluminescent layer for one color exists.

As heretofore described, in the embodiment, it is possible to realize an organic electroluminescent display device without forming the bank 8. Then, as it is possible, there being no need for a patterning, to form the transparent conduction film 14 on the lower electrode 13 thinly, it is possible, while maintaining a superior color purity, to realize an increase in a manufacturing yield rate, and a reduction in a manufacturing cost.

### Third Embodiment

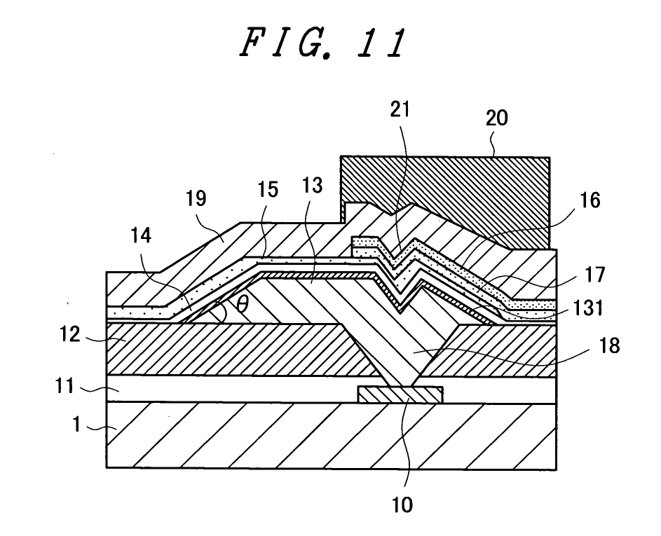

FIG. 11 is a sectional view of a pixel portion of a third embodiment of the invention. As with the second embodiment, the present embodiment does not form the bank 8 either. What the present embodiment differs from the second embodiment is the lower electrode 13, and a surface coating 131 of the lower electrode 13. In FIG. 11, up to the formation of the planarizing film 12 is the same as the first embodiment or the second embodiment. In the embodiment, as the bank 8 is not formed, the forming of a taper of 40 degrees or less at the extremity of the lower electrode 13, and forming a plurality of organic electroluminescent layers so as to overlap each other in the contact hole 18 are the same as in the second embodiment.

In the present embodiment, an aluminum-silicon alloy is used for the lower electrode 13. This is because an aluminum-silicon alloy has a high reflectivity, and generates only a small amount of dry etching residue. The aluminum-silicon alloy is deposited, by means of a sputtering, to 120 nm, and a dry etching is carried out using BCl₃ and chlorine gas. Dry etching conditions are to cause a discharge with a low pressure of 10⁻² Pa, and carry out a reactive ion etching. A taper angle of approximately 40 degrees is formed by a method which, by making an etching rate of a photoresist and that of the aluminum-silicon approximately equal, passes a resist taper angle, as it is, on to the aluminum-silicon.

In order to lower a contact resistance between the aluminum-silicon alloy and the transparent conduction film 14, an aluminum-silicon surface modification is carried out. That is, the extremely thin surface coating 131 is formed, of zinc or zinc oxide, on the aluminum-silicon surface by treating the substrate for approximately ten seconds with a 2 to 5% by weight ZnCl₂ solution shower, and doing a purity rinse. By this means, the contact resistance is reduced and stabilized.

A thin indium zinc oxide film of a thickness of 20 nm is formed, by means of a sputtering, on the surface coating 131 as the transparent conduction film 14. For a discharge gas of argon, 2.5% by volume of oxygen is introduced, and an adjustment is made to an indium zinc oxide film with a resistivity of 10 to 300 Ω·cm. Although a fluctuation of a resistance value is quite large, as the resistance of the organic electroluminescent layer is considerably larger than this, there is no problem as long as the resistance value is within this range.

In the same way as with the indium tin oxide in the first embodiment and second embodiment, it is possible to evaporate the indium zinc tin oxide of the present embodiment over the whole of the substrate. Although the indium zinc oxide film is deposited over the terminal unit and between terminal units, as long as a thickness of the indium zinc oxide film is 5 to 20 nm, and a resistivity is in a range of 1 to 10⁵ Ω·cm, the kind of phenomenon that the resistance in the terminal unit is too high, or the resistance between the terminal units becomes small and the insulation cannot be maintained, does not occur. Furthermore, its being possible to widen the range of the indium zinc oxide film resistivity to 0.1 to 10⁶ Ω·cm, by masking between the terminals and sputtering, is also the same as in the first embodiment. In this case too, it is more desirable that the thickness of the indium zinc oxide film is 10 to 20 nm. This is because, by being in this range, the indium zinc oxide can exist more stably as a film.

The hole transport layer, the light emitting layer, the electron transport layer, and the electron injection layer of the organic electroluminescent layer are formed on the indium zinc oxide, and indium zinc oxide is formed on top of that as the upper electrode 19. Furthermore, the auxiliary electrode is formed so as to cover the contact hole 18. The configuration of each film is as follows. That is, the aluminum-silicon layer, as the lower electrode 13, is commonly formed in each layer to 120 nm, the transparent conduction film 14 to 20 nm, and the hole transport layer to 120 nm.

Subsequently, the blue portion forms the light emitting layer to 40 nm, the green portion the hole transport layer to 60 nm and the light emitting layer to 40 nm, and the red portion the hole transport layer to 130 nm and the light emitting layer to 30 nm. On top thereof, the electron transport layer is formed to 10 nm, the electron injection layer to 60 nm, and an upper indium zinc oxide cathode to 30 nm, commonly in each layer.

The hole transport layer and light emitting layer formed separately for each color are formed so as to overlap at a border portion of each color and the organic electroluminescent layers are caused to overlap at the contact hole 18 so that the lower electrode 13 and the upper electrode 19 do not short circuit in the contact hole 18. By applying a positive voltage to the lower electrode 13 and a negative voltage to the upper electrode 19, the organic electroluminescent layer emits a light. A plan view of a pixel arrangement according to the present embodiment is the same as FIGS. 9 and 10 in the second embodiment.

Although, in the present embodiment, aluminum-silicon is used as the lower electrode 13, it is also possible to form the thin film 131 of zinc or zinc oxide on the surface by using aluminum-neodymium or aluminum-copper. Furthermore, in the present embodiment, the transparent conduction film 14 on the lower electrode 13 is taken to be indium zinc oxide but, not being limited to this, it is possible to acquire the same kind of advantage even when it is indium tin oxide.

As heretofore described, according to the present embodiment, as the transparent conduction film 14 on the lower electrode 13 is deposited over the whole of the substrate, and subsequent processing of the transparent conduction film 14 is unnecessary, it is possible to reduce the manufacturing cost. Also, as the thickness of the transparent conduction film 14 is extremely small, the color purity of the light emitted from the organic electroluminescent layer is not deteriorated. Also, it is possible to make the contact resistance between the lower electrode 13 and the indium zinc oxide forming the transparent conduction film 14 low and stabilized.

What is claimed is:

1. An organic electroluminescent display device including a display area in which pixels having a lower electrode, an organic electroluminescent layer and an upper electrode are formed in a matrix, and the lower electrodes are divided by an insulating film for each pixel, and a terminal formed on an external side of the display area, the device comprising:
a transparent conduction film between the lower electrode and the organic electroluminescent layer, wherein
the transparent conduction film, is also formed continuously on the insulating film between a first lower electrode and a second lower electrode neighboring the first lower electrode.

2. The organic electroluminescent display device according to claim 1, wherein
the thickness of the transparent conduction film is 5 to 20 nm, and the resistivity thereof is 1 to 10⁵ Ω·cm.

3. The organic electroluminescent display device according to claim 1, wherein
the thickness of the transparent conduction film is 10 to 20 nm, and the resistivity thereof is 1 to 105 Ω·cm.

4. The organic electroluminescent display device according to claim 2, wherein
the transparent conduction film is also formed as a continuous film between the first electrode and second electrode.

5. The organic electroluminescent display device according to claim 1, wherein
the transparent conduction film is of indium tin oxide or indium zinc oxide.

6. The organic electroluminescent display device according to claim 1, wherein
the lower electrode is formed of an aluminum-zinc alloy, an aluminum-nickel alloy, or an aluminum-silicon alloy.

7. An organic electroluminescent display device in which pixels having a lower electrode, an organic electroluminescent layer, and an upper electrode are formed in a matrix to form a display area, and a terminal is formed on an external side of the display area, wherein
a transparent conduction film is formed between the lower electrode and the organic electroluminescent layer, a thin film made of zinc or zinc oxide is formed between the transparent conduction film and the lower electrode, and
the transparent conduction film is also formed continuously between a first lower electrode and a second lower electrode.

8. The organic electroluminescent display device according to claim 7, wherein
the transparent conduction film is of indium zinc oxide.

9. The organic electroluminescent display device according to claim 7, wherein
the lower electrode is formed of any one of an aluminum-silicon alloy, an aluminum-neodymium alloy, or an aluminum-copper alloy.
